(19) United States
(12) Patent Application Publication
(10) Pub. No.: US 2009/0220782 A1
(43) Pub. Date: Sep. 3, 2009

(54) Method of Forming Gallium Arsenide-On-Insulator

(75) Inventors: Ching Kean CHIA, Singapore (SG); Dongzhi CHI, Singapore (SG); Jianrong DONG, Singapore (SG); Aaditya SRIDHARA, Singapore (SG)

Correspondence Address: WOMBLE CARLYLE SANDRIDGE & RICE, PLLC, ATTN: PATENT DOCKETING, P.O. BOX 7037, ATLANTA, GA, 30357-0037, US

(73) Assignee: Agency for Science, Technology and Research, Singapore (SG)

(21) Appl. No.: 12/388,562

(22) Filed: Feb. 19, 2009

Related U.S. Application Data
(60) Provisional application No. 61/030,410, filed on Feb. 21, 2008.

(51) Int. Cl. H01L 21/20; B32B 9/04

(52) U.S. Cl. 428/336; 438/479; 428/689; 428/446; 257/632

(57) ABSTRACT

A method of forming gallium arsenide (GaAs)-on-insulator includes providing a substrate and forming a diffusion barrier layer of a compound of formula AlₓGa₁₋ₓAs on the substrate. A layer of GaAs is formed on the diffusion barrier layer of AlₓGa₁₋ₓAs. The layer of AlₓGa₁₋ₓAs is substantially completely oxidized to transform the layer of AlₓGa₁₋ₓAs into an electrical insulator as well as a diffusion barrier.

### REFERENCE TO RELATED APPLICATIONS

This application claims priority to U.S. Provisional Patent Application Ser. No. 61/030,410 filed Feb. 21, 2008, and entitled “High Purity Film on Insulator Utilizing a Dual-Function Diffusion-Blocking Turned Insulating Layer”, the priority of which is hereby claimed and the contents of which are incorporated herein by reference as if disclosed herein in their entirety.

### BACKGROUND OF THE INVENTION

The present invention relates generally to the formation of gallium arsenide (GaAs)-on-insulator.

In microelectronic applications, complementary metal oxide semiconductor (CMOS) devices that are built on an insulator exhibit improved characteristics over CMOS devices fabricated on bulk substrates. These include higher drive currents, reduced source/drain capacitance, reduced short channel effects, reduced parasitic leakages, better sub-threshold slopes and no latch-up. The improved characteristics achieved by CMOS-on-insulator are particularly desirable for gallium arsenide (GaAs) devices built on germanium (Ge) bulk substrates and Ge containing substrates because at temperatures greater than about 250 degrees Celsius (° C.), the Ge bulk substrates or Ge containing substrates begin to conduct significant amounts of current due to their small bandgap. Accordingly, it would be desirable to have a method of forming GaAs-on-insulator.

### SUMMARY OF THE INVENTION

Accordingly, in one aspect, the present invention is directed to a method of forming gallium arsenide (GaAs)-on-insulator including the steps of providing a substrate and forming a diffusion barrier layer of a compound of formula AlₓGa₁₋ₓAs on the substrate. A layer of GaAs is formed on the diffusion barrier layer of AlₓGa₁₋ₓAs. The layer of AlₓGa₁₋ₓAs is substantially completely oxidized to transform the layer of AlₓGa₁₋ₓAs into an electrical insulator as well as a diffusion barrier.

In another aspect, the present invention is directed to a gallium arsenide (GaAs)-on-insulator structure including a substrate, a layer of GaAs and a substantially completely oxidized layer of a compound of formula AlₓGa₁₋ₓAs between the substrate and the layer of GaAs. The substantially completely oxidized layer of AlₓGa₁₋ₓAs is both an electrical insulator as well as a diffusion barrier.

Other aspects and advantages of the invention will become apparent from the following detailed description, taken in conjunction with the appended drawings, illustrating by way of example the principles of the invention.

### BRIEF DESCRIPTION OF THE DRAWINGS

The following detailed description of preferred embodiments of the invention will be better understood when read in conjunction with the appended drawings. The present invention is illustrated by way of example and is not limited by the accompanying figures.

FIGS. 1A through 1C illustrate a method of forming gallium arsenide (GaAs) in accordance with an exemplary embodiment of the present invention;

FIGS. 2A through 2D show GaAs structures grown on a Ge substrate at a temperature of about 650° C.;

FIGS. 3A through 3D show secondary ion mass spectroscopy (SIMS) profiles of the GaAs structures of FIGS. 2A through 2D; and

FIG. 4 shows photoluminescence spectra of GaAs structures.

### DETAILED DESCRIPTION OF THE INVENTION

The detailed description set forth below in connection with the appended drawings is intended as a description of the presently preferred embodiments of the invention, and is not intended to represent the only forms in which the present invention may be practiced. It is to be understood that the same or equivalent functions may be accomplished by different embodiments that are intended to be encompassed within the spirit and scope of the invention.

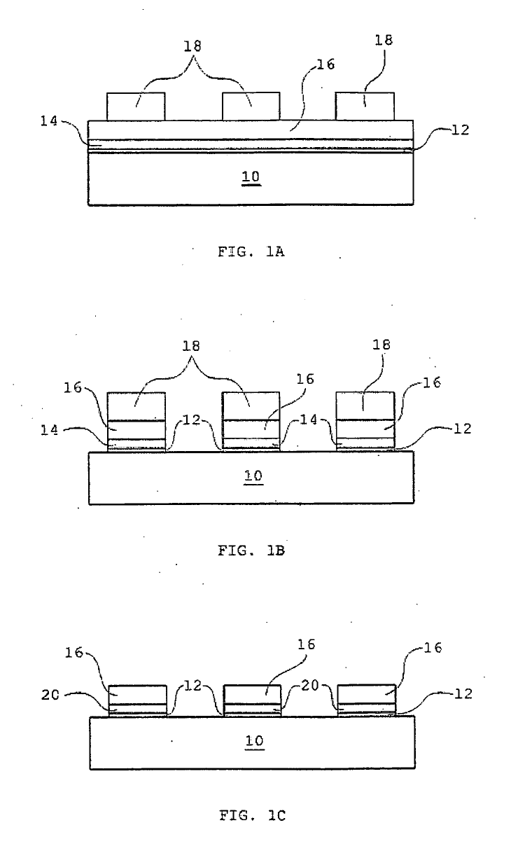

Referring now to FIG. 1A, a substrate 10 is provided as shown. In the embodiment shown, a first layer of gallium arsenide (GaAs) 12 is formed on the substrate 10, following which a diffusion barrier layer of a compound of formula AlₓGa₁₋ₓAs 14 is formed on the substrate 10 over the first layer of GaAs 12. A second layer of GaAs 16 is formed on the diffusion barrier layer of AlₓGa₁₋ₓAs 14, and a mask 18 is formed on the second layer of GaAs 16.

The substrate 10 may be a semiconductor substrate such as, for example, a germanium (Ge) bulk substrate, a silicon (Si) bulk substrate, a germanium-on-insulator (GeOI) substrate, a silicon-on-insulator (SiOI) substrate, a silicon germinide (SiGe) substrate, a SiGe/Si substrate, or a Ge/SiGe/Si substrate. Such substrates are well known in the art and commercially available. The substrate 10 may have a thickness of between about 2 microns (μm) and about 500 μm. Although an unpatterned substrate is illustrated in the present embodiment, it should be understood that the present invention is not limited to such substrates and may be implemented on a patterned substrate in alternative embodiments.

The first layer of GaAs 12 may be formed on the substrate 10 using Molecular-Beam Epitaxy (MBE), Metal-Organic Chemical Vapor Deposition (MOCVD), Pulsed Laser Deposition (PLD), Liquid Phase Epitaxy (LPE), Chemical Vapor Deposition (CVD), sputtering, or combinations thereof, as are known to those of ordinary skill in the art. The first layer of GaAs 12 may be formed at a temperature of between about 550 degrees Celsius (° C.) and about 680° C. The first layer of GaAs 12 may be formed to a thickness of between about 0.3 nanometers (nm) and about 50 nm. Advantageously, the formation of an initial layer of GaAs 12 on the substrate 10 before forming the layer AlₓGa₁₋ₓAs 14 helps to increase lattice matching between the substrate 10 and the subsequently grown layer of GaAs 16. It should however be understood by those of ordinary skill in the art that the first layer of GaAs 12 is optionally provided. In embodiments where the first layer of GaAs 12 is not provided, the diffusion barrier layer of AlₓGa₁₋ₓAs 14 may be formed directly on the substrate 10.

In the formula AlₓGa₁₋ₓAs, Al represents aluminium, Ga represents gallium, As represents arsenide, and x may be greater than or equal to about 0.5 and less than or equal to 1, more preferably, greater than or equal to about 0.8 and less than or equal to 1. The layer of AlₓGa₁₋ₓAs 14 may be formed by MBE, MOCVD, PLD, LPE, CVD, sputtering, or combinations thereof, as are known to those of ordinary skill in the art. The diffusion barrier layer of AlₓGa₁₋ₓAs 14 may be formed to a thickness of between about 10 nm and about 2 μm, more preferably, between about 0.5 μm and about 1 μm. The layer of AlₓGa₁₋ₓAs 14, provided as an interfacial layer interfacing the substrate 10 and the second GaAs layer 16, serves to block diffusion of atoms from the substrate 10 into the second GaAs layer 16, as well as diffusion of gallium (Ga) and arsenide (As) atoms into the substrate 10, during epitaxial growth of the second GaAs layer 16. This reduces contamination of the GaAs crystals in the second GaAs layer 16 during epitaxial growth and thereby enables formation of GaAs crystals of greater purity.

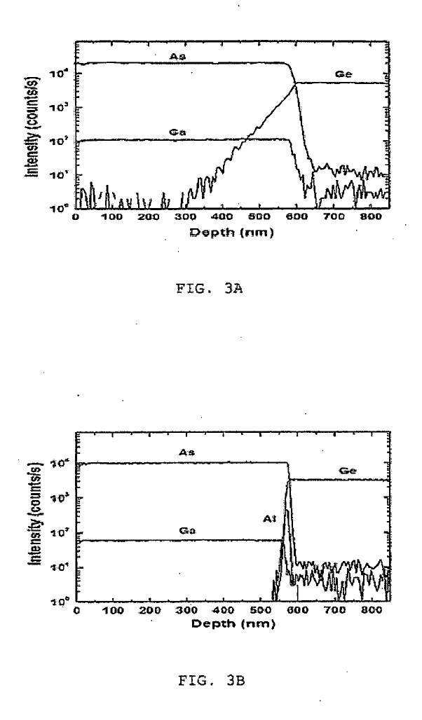

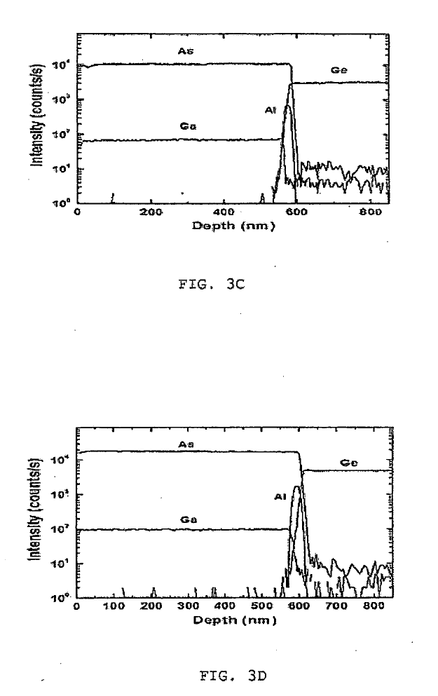

Inhibition of the outdiffusion of substrate atoms to the GaAs crystals, through the provision of the interfacial layer of AlₓGa₁₋ₓAs 14, renders possible the growth of GaAs crystals of greater purity at higher temperatures which is desirable for optimum GaAs crystal growth. Consequently, the second layer of GaAs 16 may be formed on the layer of AlₓGa₁₋ₓAs 14 at a temperature of between about 550° C. and about 680° C. The purity of the GaAs crystals formed may be evidenced by the presence of abrupt interfacial profiles between the layer of AlₓGa₁₋ₓAs 14 and the second layer of GaAs 16, shown in FIGS. 3B through 3D. The second layer of GaAs 16 may be formed by MBE, MOCVD, PLD, LPE, CVD, sputtering, or combinations thereof, as are known to those of ordinary skill in the art. The second layer of GaAs 16 may be formed to a thickness of between about 5 nm and about 1 μm.

The mask 18 may comprise silicon dioxide (SiO₂) and may be formed on the second layer of GaAs 16 by, for example, sputtering, Plasma Enhanced Chemical Vapour Deposition (PECVD), spin coating of silica film or any other known method of mask formation.

Referring now to FIG. 1B, portions of the first layer of GaAs 12, the layer of AlₓGa₁₋ₓAs 14 and the second layer of GaAs 16 are etched away with the mask 18 as shown.

The first layer of GaAs 12, the layer of AlₓGa₁₋ₓAs 14 and the second layer of GaAs 16 may be patterned using a dry etch and/or wet etch process. Such etching processes are well known to those of ordinary skill in the art. Accordingly, detailed description thereof is not required for a complete understanding of the present invention.

Referring now to FIG. 1C, the diffusion barrier layer of AlₓGa₁₋ₓAs 14 is substantially completely oxidized to transform it into an insulating oxide layer 20, and the mask 18 is removed as shown.

The layer of AlₓGa₁₋ₓAs 14 may be oxidized via an oxidation process such as, for example, hydrolyzation oxidation, rapid thermal oxidation or oxygen furnace oxidation. The oxidation process transforms the layer of AlₓGa₁₋ₓAs 14 into an electrical insulator as well as a diffusion layer. Advantageously, oxidation of the interfacial layer of AlₓGa₁₋ₓAs 14 into the insulating oxide layer 20 results in the formation of a structure of substantially pure GaAs on an insulator. This is advantageous as GaAs devices built on insulators are known to possess superior properties similar to devices on Silicon-On-Insulator (SOI) or Germanium-On-Insulator (GOI), including higher drive currents, reduced source/drain capacitance, reduced short channel effects and parasitic leakages, better sub-threshold slopes and no latch-up. The layer of AlₓGa₁₋ₓAs 14 may be substantially completely oxidized for complete current insulation.

The mask 18 may be removed by a buffer HF or HF aqueous solution.

Although described in a particular order, it should be understood by those of ordinary skill in the art that the present invention is not limited to the order described. For example, the mask 18 may be formed on the substrate 10 before the layer of AlₓGa₁₋ₓAs 14 is formed on the substrate 10 in an alternative embodiment. In another embodiment, the layer of AlₓGa₁₋ₓAs 14 may be oxidized immediately after a portion of the second layer of GaAs 16 is etched away, and before the layer of AlₓGa₁₋ₓAs 14 is etched. Further, the steps may be repeated to form repetitive layers and/or further layers of Group III-V or Group-IV materials or combinations thereof may be added.

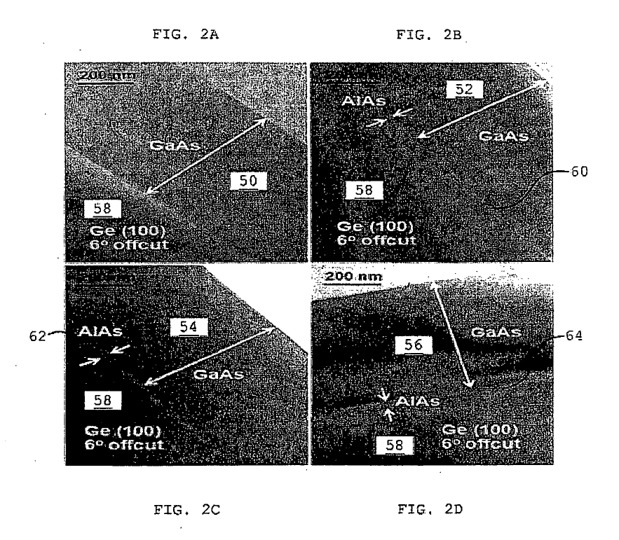

Referring now to FIGS. 2A through 2D, GaAs structures 50, 52, 54 and 56 grown on a Ge (100) 6° offcut substrate 58 at a temperature of about 650° C. are shown. The GaAs structures 50, 52, 54 and 56 are grown to a thickness of about 590 nm. FIGS. 2A through 2D are obtained from transmission electron microscopy (TEM) images of the GaAs structures 50, 52, 54 and 56. FIG. 2A shows a first GaAs structure 50 grown directly on the Ge substrate 58, FIG. 2B shows a second GaAs structure 52 grown on a 9.5 nm thick interfacial layer of aluminium arsenide (AlAs) 60, FIG. 2C shows a third GaAs structure 54 grown on a 20 nm thick interfacial layer of AlAs 62, and FIG. 2D shows a fourth GaAs structure 56 grown on a 29 nm thick interfacial layer of AlAs 64.

Referring now to FIGS. 3A through 3D, graphs of secondary ion mass intensities of each element in the structures of FIGS. 2A through 2D at various depths are shown. The graphs of FIGS. 3A through 3D are obtained from secondary ion mass spectroscopy (SIMS) measurements performed on the first, second, third, and fourth GaAs structures 50, 52, 54 and 56 of FIGS. 2A through 2D. As can be seen from FIG. 3A, Ge atoms diffuse to a depth of up to about 300 nm into the first GaAs structure 50 when the GaAs structure 50 is grown directly on the Ge substrate 58. However, as shown in FIGS. 3B through 3D, outdiffusion of Ge atoms to the GaAs structures 52, 54 and 56 is substantially reduced when the GaAs structures 52, 54 and 56 are formed on AlAs layers 60, 62 and 64 of varying thicknesses. In such instances, the outdiffusion of Ge atoms is largely confined to the AlAs layers 60, 62 and 64.

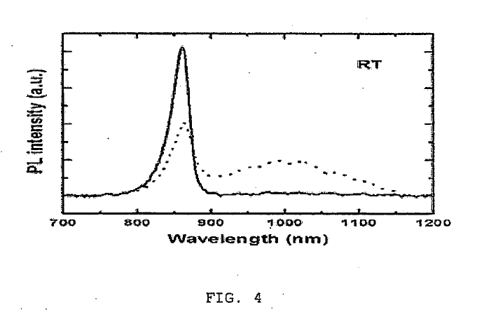

Referring now to FIG. 4, a graph of photoluminescence (PL) against wavelength is shown. Room temperature PL spectra for GaAs formed on an interfacial layer of of AlₓGa₁₋ₓAs is represented by a solid line, while GaAs formed directly on a substrate, without an interfacial layer therebetween is represented by the dotted line. The broad inner-bandgap emissions at 900-1200 nm are due to Ge complexes formed in the GaAs layer. The photoluminescence (PL) measurements show that emissions from Ge-based complexes in the GaAs layer at 900-1200 nm that appear in the spectrum for a GaAs/Ge structure (see dotted line in FIG. 4) is absent from the spectrum for a GaAs/AlAs/Ge structure (see solid line in FIG. 4).

As is evident from the foregoing discussion, the present invention provides a method of forming gallium arsenide (GaAs)-on-insulator and a gallium arsenide (GaAs)-on-insulator structure. Although gallium arsenide (GaAs) and germanium (Ge) have very similar thermal expansion coefficients and are also substantially lattice matched at room temperature, there is considerable difficulty forming GaAs crystals of substantial purity for various device applications on a Ge or Ge containing substrate due to the outdiffusion of Ge atoms to the GaAs layer during epitaxial growth, resulting in contamination of the GaAs crystals. Accordingly, in order to prepare a high purity GaAs layer on an insulator on a Ge or Ge containing substrate, an AlₓGa₁₋ₓAs interfacial layer is first grown on the Ge or Ge containing substrate. This allows the subsequent GaAs layer to be grown at its optimum temperature as the AlₓGa₁₋ₓAs layer with high atomic energy bonding stops the outdiffusion of Ge atoms into the GaAs layer. The AlₓGa₁₋ₓAs layer is subsequently converted into an insulating oxide layer by an oxidation process, resulting in high purity GaAs-on-insulator.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiments disclosed, but covers modifications within the spirit and scope of the present invention as defined by the appended claims.

1. A method of forming gallium arsenide (GaAs)-on-insulator, comprising:
providing a substrate;
forming a diffusion barrier layer of a compound of formula AlₓGa₁₋ₓAs on the substrate;
forming a layer of GaAs on the diffusion barrier layer of AlₓGa₁₋ₓAs; and
substantially completely oxidising the layer of AlₓGa₁₋ₓAs to transform the layer of AlₓGa₁₋ₓAs into an electrical insulator as well as the diffusion barrier.

2. The method of forming GaAs-on-insulator of claim 1, wherein x is greater than or equal to about 0.5 and less than or equal to 1.

3. The method of forming GaAs-on-insulator of claim 2, wherein x is greater than or equal to about 0.8 and less than or equal to 1.

4. The method of forming GaAs-on-insulator of claim 1, wherein the diffusion barrier layer of AlₓGa₁₋ₓAs is formed to a thickness of between about 10 nanometers (nm) and about 2 microns (μm).

5. The method of forming GaAs-on-insulator of claim 4, wherein the diffusion barrier layer of AlₓGa₁₋ₓAs is formed to a thickness of between about 0.5 μm and about 1 μm.

6. The method of forming GaAs-on-insulator of claim 1, wherein the substrate is one of a group comprising a germanium (Ge) bulk substrate, a silicon (Si) bulk substrate, a germanium-on-insulator (GeOI) substrate, a silicon-on-insulator (SiOI) substrate, a silicon germinide (SiGe) substrate, a SiGe/Si substrate, and a Ge/SiGe/Si substrate.

7. The method of forming GaAs-on-insulator of claim 1, further comprising forming an initial layer of GaAs on the substrate before forming the diffusion barrier layer of AlₓGa₁₋ₓAs.

8. The method of forming GaAs-on-insulator of claim 7, wherein the initial layer of GaAs is formed to a thickness of between about 0.3 nm and about 50 nm.

9. A gallium arsenide (GaAs)-on-insulator structure, comprising:
a substrate;
a layer of GaAs; and
a substantially completely oxidized layer of a compound of formula AlₓGa₁₋ₓAs between the substrate and the layer of GaAs, wherein the substantially completely oxidized layer of AlₓGa₁₋ₓAs is both an electrical insulator as well as a diffusion barrier.

10. The GaAs-on-insulator structure of claim 9, wherein x is greater than or equal to about 0.5 and less than or equal to 1.

11. The GaAs-on-insulator structure of claim 10, wherein x is greater than or equal to about 0.8 and less than or equal to 1.

12. The GaAs-on-insulator structure of claim 9, wherein the substantially completely oxidized layer of AlₓGa₁₋ₓAs is of a thickness of between about 10 nanometers (nm) and about 2 microns (μm).

13. The GaAs-on-insulator structure of claim 12, wherein the substantially completely oxidized layer of AlₓGa₁₋ₓAs is of a thickness of between about 0.5 μm and about 1 μm.

14. The GaAs-on-insulator structure of claim 9, wherein the substrate is one of a group comprising a germanium (Ge) bulk substrate, a silicon (Si) bulk substrate, a germanium-on-insulator (GeOI) substrate, a silicon-on-insulator (SiOI) substrate, a silicon germinide (SiGe) substrate, a SiGe/Si substrate, and a Ge/SiGe/Si substrate.

15. The GaAs-on-insulator structure of claim 9, further comprising an initial layer of GaAs formed on the substrate before the substantially completely oxidized layer of AlₓGa₁₋ₓAs is formed.

16. The GaAs-on-insulator structure of claim 9, wherein the initial layer of GaAs is of a thickness of between about 0.3 nm and about 50 nm.
